(19) United States
(12) Patent Application Publication
(10) Pub. No.: US 2025/0044370 A1
(43) Pub. Date: Feb. 6, 2025

(54) POWER SUPPLY CONTROL DEVICE AND FAILURE DETECTION METHOD

(71) Applicants: AutoNetworks Technologies, Ltd., Yokkaichi-Shi, Mie (JP); Sumitomo Wiring Systems, Ltd., Yokkaichi-Shi, Mie (JP); Sumitomo Electric Industries, Ltd., Osaka-Shi, Osaka (JP)

(72) Inventors: Koki SAKAKIBARA, Yokkaichi-Shi, Mie (JP); Kota ODA, Yokkaich-Shi, Mie (JP)

(73) Assignees: AutoNetworks Technologies, Ltd., Yokkaichi-Shi, Mie (JP); Sumitomo Wiring Systems, Ltd., Yokkaichi-Shi, Mie (JP); Sumitomo Electric Industries, Ltd., Osaka-Shi, Osaka (JP)

(21) Appl. No.: 18/719,480

(22) PCT Filed: Nov. 29, 2022
(86) PCT No.: PCT/JP2022/043844

§ 371 Date: Jun. 13, 2024

(30) Foreign Application Priority Data
Dec. 17, 2021 (JP) 2021-205402

(51) Int. Cl. G01R 31/40; G01R 31/327

(52) U.S. Cl. CPC G01R 31/40; G01R 31/3277

(57) ABSTRACT

In a power supply control device, an upstream switch and a downstream switch are respectively disposed upstream and downstream of a load in a current path for a current flowing through the load. One end of a first resistor is connected to a connection node between the upstream switch and the load. One end of a series circuit including a connection switch and a second resistor is connected to a connection node between the load and the downstream switch. A constant voltage is applied to the other end of the series circuit. A microcomputer detects any failure of the upstream switch, the downstream switch, and the load based on one of the values of voltages at the two connection nodes.

### CROSS-REFERENCE TO RELATED APPLICATIONS

This application is the U.S. national stage of PCT/JP2022/043844 filed on Nov. 29, 2022, which claims priority of Japanese Patent Application No. JP 2021-205402 filed on Dec. 17, 2021, the contents of which are incorporated herein.

### TECHNICAL FIELD

The present disclosure relates to a power supply control device and a failure detection method.

### BACKGROUND

JP 2019-41508 discloses a power supply control device for vehicles that controls power supply from a DC power source to a load. A switch is disposed on a current path through which a current flows from the DC power source to the load. By giving an instruction to turn on or off the switch, the control device controls the power supply to the load.

In the configuration of JP 2019-41508, if a short circuit failure where the resistance value between the two ends of the switch is very small occurs although the control device has given an instruction to turn off the switch, the DC power source continues to supply power to the load. In this case, the power from the DC power source may be wasted.

The present disclosure was made in view of such circumstances and an object thereof is to provide a power supply control device that is capable of stopping the power supply to a load upon occurrence of a short circuit failure, and a failure detection method for detecting a failure of a circuit capable of stopping the power supply to a load upon occurrence of a short circuit failure.

### SUMMARY

A power supply control device according to an aspect of the present disclosure is directed to a power supply control device for controlling power supply to a load, including: an upstream switch disposed upstream of the load in a current path for a current flowing through the load; a downstream switch disposed downstream of the load in the current path; a first resistor whose one end is connected to a connection node between the upstream switch and the load; a series circuit whose one end is connected to a connection node between the load and the downstream switch, the series circuit including a second resistor and a connection switch that are connected in series to each other; and a processing unit configured to execute processing, wherein a constant voltage with respect to a potential of another end of the first resistor serving as a reference potential is applied to another end of the series circuit, and the processing unit is configured to: obtain a voltage value of a voltage at the connection node between the upstream switch and the load, or a voltage value of a voltage at the connection node between the load and the downstream switch, and detect a failure of the upstream switch, the downstream switch, or the load based on the obtained voltage value.

A failure detection method according to an aspect of the present disclosure is directed to a failure detection method for detecting a failure of a circuit, the circuit including: an upstream switch disposed upstream of a load in a current path for a current flowing through the load; a downstream switch disposed downstream of the load in the current path; a first resistor whose one end is connected to a connection node between the upstream switch and the load; and a series circuit whose one end is connected to a connection node between the load and the downstream switch, the series circuit including a second resistor and a connection switch that are connected in series to each other, a constant voltage with respect to a potential of another end of the first resistor serving as a reference potential being applied to another end of the series circuit, the method including the steps, executed by a computer, of obtaining a voltage value of a voltage at the connection node between the upstream switch and the load, or a voltage value of a voltage at the connection node between the load and the downstream switch; and detecting any failure of the upstream switch, the downstream switch, and the load based on the obtained voltage value.

Note that the present disclosure can be realized not only as a power supply control device including such a characteristic processing unit, but also as a failure detection method including such characteristic processing as steps, or as a computer program for causing a computer to execute the steps. The present disclosure can also be realized as an integrated semiconductor circuit that realizes a part of or the entire power supply control device, or as a power source system including the power supply control device.

### Advantageous Effects

With the power supply control device according to the above-described aspect, it is possible to stop the power supply to a load upon occurrence of a short circuit failure.

With the failure detection method according to the above-described aspect, a failure of a circuit capable of stopping the power supply to a load upon occurrence of a short circuit failure is detected.

### BRIEF DESCRIPTION OF DRAWINGS

FIG. 1 is a block diagram illustrating a configuration of the main part of a power source system according to Embodiment 1.

FIG. 2 is a block diagram illustrating a configuration of the main part of a microcomputer.

FIG. 3 is a diagram illustrating a plurality of thresholds.

FIG. 4 is a table illustrating failure diagnosis when a load is stopped.

FIG. 5 is a table illustrating failure diagnosis when the load is operating.

FIG. 6 is a flowchart illustrating a procedure of power supply control processing.

FIG. 7 is a block diagram illustrating a configuration of the main part of a power supply control device according to Embodiment 2.

### DETAILED DESCRIPTION OF PREFERRED EMBODIMENTS

First, embodiments of the present disclosure are listed and described. At least some of the embodiments described below may be combined with each other as appropriate.

A power supply control device according to an aspect of the present disclosure is directed to a power supply control device for controlling power supply to a load, including: an upstream switch disposed upstream of the load in a current path for a current flowing through the load; a downstream switch disposed downstream of the load in the current path; a first resistor whose one end is connected to a connection node between the upstream switch and the load; a series circuit whose one end is connected to a connection node between the load and the downstream switch, the series circuit including a second resistor and a connection switch that are connected in series to each other; and a processing unit configured to execute processing, wherein a constant voltage with respect to a potential of another end of the first resistor serving as a reference potential is applied to another end of the series circuit, and the processing unit is configured to: obtain a voltage value of a voltage at the connection node between the upstream switch and the load, or a voltage value of a voltage at the connection node between the load and the downstream switch, and detect a failure of the upstream switch, the downstream switch, or the load based on the obtained voltage value.

According to the above-described aspect, a short circuit failure of a switch is a phenomenon in which the resistance value between the two ends of the switch is very small although an instruction to turn off the switch has been given. If a short circuit failure occurs in the upstream switch, power supply to the load is stopped by turning off the downstream switch. The processing unit detects a failure of the upstream switch, the downstream switch, or the load based on the voltage value of a voltage at the connection node between the upstream switch and the load, or a voltage value of a voltage at the connection node between the load and the downstream switch.

In the power supply control device according to an aspect of the present disclosure, a current flows from one end of a DC power source to another end of the DC power source through the current path, the processing unit is configured to: give an instruction to turn on the upstream switch, give an instruction to turn off the downstream switch, and obtain a voltage value of a voltage at the connection node between the upstream switch and the load, or a voltage value of a voltage at the connection node between the load and the downstream switch, while the connection switch is off, and detect an open circuit failure of the upstream switch when the obtained voltage value is less than a voltage threshold, and the voltage threshold exceeds 0 V and is less than or equal to a value of a voltage between the one end and the other end of the DC power source.

According to the above-described aspect, when the upstream switch, the downstream switch, and the connection switch are respectively on, off, and off, the voltage value obtained by the processing unit is the voltage value of a voltage between the two ends of the DC power source, and is greater than or equal to the voltage threshold. An open circuit failure of a switch is a phenomenon in which the resistance value between the two ends of the switch is substantially high although an instruction to turn on the switch has been given. When an instruction to turn on the upstream switch and an instruction to turn off the downstream switch have been given, and an open circuit failure has occurred in the upstream switch, the voltage value obtained by the processing unit while the connection switch is off is 0 V and is less than the voltage threshold.

In the power supply control device according to an aspect of the present disclosure, a current flows from one end of a DC power source to another end of the DC power source through the current path, the processing unit is configured to: give instructions to turn off the upstream switch and the downstream switch, obtain a voltage value of a voltage at the connection node between the upstream switch and the load, or a voltage value of a voltage at the connection node between the load and the downstream switch, while the connection switch is off, and detect a short circuit failure of the upstream switch when the obtained voltage value exceeds a second voltage threshold, and the second voltage threshold is 0 V or more and is less than a value of a voltage between the one end and the other end of the DC power source.

According to the above-described aspect, when all of the upstream switch, the downstream switch, and the connection switch are off, the voltage value obtained by the processing unit is 0 V and is less than or equal to the second voltage threshold. When instructions to turn off the upstream switch and the downstream switch have been given, and a short circuit failure has occurred in the upstream switch, the voltage value obtained by the processing unit is the voltage value of a voltage between the two ends of the DC power source, and exceeds the second voltage threshold.

In the power supply control device according to an aspect of the present disclosure, the processing unit is configured to: give an instruction to turn off the upstream switch; give an instruction to turn on the downstream switch; obtain a voltage value of a voltage at the connection node between the upstream switch and the load, or a voltage value of a voltage at the connection node between the load and the downstream switch, while the connection switch is on; and detect an open circuit failure of the downstream switch when the obtained voltage value exceeds a third voltage threshold, and the third voltage threshold is 0 V or more, and is less than a voltage value obtained by the processing unit when the upstream switch, the downstream switch, and the connection switch are respectively off, off, and on.

According to the above-described aspect, when the upstream switch, the downstream switch, and the connection switch are respectively off, on, and on, the voltage value obtained by the processing unit is 0 V and is less than or equal to the third voltage threshold. When the upstream switch, the downstream switch, and the connection switch are respectively off, off, and on, the first resistor, the second resistor, and the load divide the constant voltage. The voltage value obtained by the processing unit when the upstream switch, the downstream switch, and the connection switch are respectively off, off, and on is referred to as “divided voltage value”. When an instruction to turn off the upstream switch and an instruction to turn on the downstream switch have been given, and an open circuit failure has occurred in the downstream switch, the voltage value obtained by the processing unit while the connection switch is on is the divided voltage value, and exceeds the third voltage threshold.

In the power supply control device according to an aspect of the present disclosure, the processing unit is configured to: give instructions to turn off the upstream switch and the downstream switch, obtain a voltage value of a voltage at the connection node between the upstream switch and the load, or a voltage value of a voltage at the connection node between the load and the downstream switch, while the connection switch is on; and detect a short circuit failure of the downstream switch when the obtained voltage value is less than a fourth voltage threshold, and the fourth voltage threshold exceeds 0 V and is less than or equal to a voltage value obtained by the processing unit when the upstream switch, the downstream switch, and the connection switch are respectively off, off, and on.

According to the above-described aspect, when the upstream switch, the downstream switch, and the connection switch are respectively off, off, and on, the voltage value obtained by the processing unit is a divided voltage value, and is greater than or equal to the fourth voltage threshold. When instructions to turn off the upstream switch and the downstream switch have been given, and a short circuit failure has occurred in the downstream switch, the voltage value obtained by the processing unit while the connection switch is on is 0 V and is less than the fourth voltage threshold.

In the power supply control device according to an aspect of the present disclosure, the processing unit is configured to: give instructions to turn off the upstream switch and the downstream switch; obtain a voltage value of a voltage at the connection node between the load and the downstream switch while the connection switch is on; and detect an open circuit failure of the load when the obtained voltage value exceeds a fifth voltage threshold, and the fifth voltage threshold exceeds a voltage value obtained by the processing unit when the upstream switch, the downstream switch, and the connection switch are respectively off, off, and on, and is less than a voltage value of the constant voltage.

According to the above-described aspect, when the upstream switch, the downstream switch, and the connection switch are respectively off, off, and on, the voltage value obtained by the processing unit while the load is normal is a divided voltage value, and is less than or equal to the fifth voltage threshold. An open circuit failure of a load is a phenomenon in which the resistance value between the two ends of the load is extremely large. According to the above-described aspect, when the upstream switch, the downstream switch, and the connection switch are respectively off, off, and on, the voltage value obtained by the processing unit is the voltage value of a constant voltage, and exceeds the fifth voltage threshold.

In the power supply control device according to an aspect of the present disclosure, a current flows from one end of a DC power source to another end of the DC power source through the current path, the processing unit is configured to: give instructions to turn on the upstream switch and the downstream switch; obtain a voltage value of a voltage at the connection node between the upstream switch and the load while the connection switch is off, and detect an open circuit failure of the upstream switch when the obtained voltage value is less than a sixth voltage threshold, and the sixth voltage threshold exceeds 0 V and is less than or equal to a value of a voltage between the one end and the other end of the DC power source.

According to the above-described aspect, when the upstream switch, the downstream switch, and the connection switch are respectively on, on, and off, the voltage value obtained by the processing unit is the voltage value of a voltage between the two ends of the DC power source, and is greater than or equal to the sixth voltage threshold. When instructions to turn on the upstream switch and the downstream switch have been given, and an open circuit failure has occurred in the upstream switch, the voltage value obtained by the processing unit while the connection switch is off is 0 V and is less than the sixth voltage threshold.

In the power supply control device according to an aspect of the present disclosure, a current flows from one end of a DC power source to another end of the DC power source through the current path, the upstream switch is a semiconductor switch, the processing unit is configured to: give instructions to turn on the upstream switch and the downstream switch; obtain a voltage value of a voltage at the connection node between the upstream switch and the load while the connection switch is off, and detect a failure regarding a resistance value of the upstream switch when the obtained voltage value is less than a seventh voltage threshold, and the seventh voltage threshold is less than or equal to a value of a voltage between the one end and the other end of the DC power source.

According to the above-described aspect, a failure regarding the resistance value of a switch is a phenomenon in which the resistance value of the switch is a halfway value, and is called “half-on failure”. According to the above-described aspect, when the upstream switch, the downstream switch, and the connection switch are respectively on, on, and off, the voltage value obtained by the processing unit is the voltage value of a voltage between the two ends of the DC power source, and is greater than or equal to the seventh voltage threshold. When instructions to turn on the upstream switch and the downstream switch have been given, and a half-on failure has occurred in the upstream switch, the voltage value obtained by the processing unit while the connection switch is off is slightly lower than the voltage value of a voltage between the two ends of the DC power source. By setting the seventh voltage threshold to a value that exceeds a voltage value slightly lower than the voltage value of the voltage between the two ends of the DC power source, and is not greater than the voltage value of the voltage between the two ends of the DC power source, it is possible to detect a half-on failure of the upstream switch.

In the power supply control device according to an aspect of the present disclosure, a current flows from one end of a DC power source to another end of the DC power source through the current path, the processing unit is configured to: give instructions to turn on the upstream switch and the downstream switch; obtain a voltage value of a voltage at the connection node between the load and the downstream switch while the connection switch is off, and detect an open circuit failure of the downstream switch when the obtained voltage value exceeds an eighth voltage threshold, and the eighth voltage threshold is 0 V or more, and is less than a value of a voltage between the one end and the other end of the DC power source.

According to the above-described aspect, when the upstream switch, the downstream switch, and the connection switch are respectively on, on, and off, the voltage value obtained by the processing unit is 0 V and is less than or equal to the eighth voltage threshold. When instructions to turn on the upstream switch and the downstream switch have been given, and an open circuit failure has occurred in the downstream switch, the voltage value obtained by the processing unit while the connection switch is off is the voltage value of a voltage between the two ends of the DC power source, and exceeds the eighth voltage threshold.

In the power supply control device according to an aspect of the present disclosure, the processing unit is configured to: give instructions to turn on the upstream switch and the downstream switch; obtain a voltage value of a voltage at the connection node between the load and the downstream switch while the connection switch is off, and detect a failure regarding a resistance value of the downstream switch when the obtained voltage value exceeds a ninth voltage threshold, and the ninth voltage threshold is 0 V or more.

According to the above-described aspect, when the upstream switch, the downstream switch, and the connection switch are respectively on, on, and off, the voltage value obtained by the processing unit is 0 V and is less than or equal to the ninth voltage threshold. When instructions to turn on the upstream switch and the downstream switch have been given, and a half-on failure has occurred in the downstream switch, the voltage value obtained by the processing unit while the connection switch is off is slightly higher than 0 V. By setting the ninth voltage threshold to a value that is 0 V or more and is less than a voltage value slightly higher than 0 V it is possible to detect a half-on failure of the downstream switch.

In the power supply control device according to an aspect of the present disclosure, the processing unit is configured to: give instructions to turn on the upstream switch and the downstream switch; obtain a current value of a current flowing through the upstream switch; and detect an open circuit failure of the load when the obtained current value is less than a current threshold, the current threshold exceeds a current value of a current flowing through the upstream switch when the upstream switch, the downstream switch, and the connection switch are respectively on, off, and off, the current threshold is less than or equal to a current value of a current flowing through the upstream switch when the upstream switch and the downstream switch are on while the load is in a normal state, and a resistance value of the load is less than a resistance value of the first resistor.

According to the above-described aspect, the current value of a current flowing through the upstream switch when the upstream switch and the downstream switch are on while the load is in a normal state is referred to as “normal current value”. The current value of a current flowing through the upstream switch when the upstream switch, the downstream switch, and the connection switch are respectively on, off, and off is referred to as “resistance current value”. The resistance current value is the current value of a current flowing through the upstream switch and the first resistor in this order. Also, the resistance value of the load is less than the resistance value of the first resistor. Accordingly, the normal current value exceeds the resistance current value.

The current value obtained by the processing unit when the upstream switch and the downstream switch are on while the load is in a normal state is the normal current value, and is not less than the current threshold. In a case where the upstream switch and the downstream switch are on, the current value obtained by the processing unit when an open circuit failure has occurred in the load is the resistance current value, and is less than the current threshold.

In the power supply control device according to an aspect of the present disclosure, the processing unit is configured to: give instructions to turn on the upstream switch and the downstream switch; obtain a current value of a current flowing through the upstream switch; and detect a short circuit failure of the load when the obtained current value exceeds a second current threshold, and the second current threshold is a current value of a current flowing through the upstream switch when the upstream switch and the downstream switch are on while the load is in a normal state.

According to the above-described aspect, a short circuit failure of a load is a phenomenon in which the resistance value between the two ends of the load is extremely small. When the upstream switch and the downstream switch are on while the load is in a normal state, the current value obtained by the processing unit is not greater than the second current threshold. When the upstream switch and the downstream switch are on, and a short circuit failure has occurred in the load, the current value obtained by the processing unit exceeds the second current threshold.

In the power supply control device according to an aspect of the present disclosure, upon detection of a failure in the upstream switch, the downstream switch, or the load when instructions to turn on the upstream switch and the downstream switch have been given, the processing unit gives instructions to turn off the upstream switch and the downstream switch.

According to the above-described aspect, upon detection of a failure in the upstream switch, the downstream switch, or the load, the processing unit gives instructions to turn off the upstream switch and the downstream switch. With this, it is possible to stop a current flow through the load.

A failure detection method according to an aspect of the present disclosure is directed to failure detection method for detecting a failure of a circuit, the circuit including: an upstream switch disposed upstream of a load in a current path for a current flowing through the load; a downstream switch disposed downstream of the load in the current path; a first resistor whose one end is connected to a connection node between the upstream switch and the load; and a series circuit whose one end is connected to a connection node between the load and the downstream switch, the series circuit including a second resistor and a connection switch that are connected in series to each other, a constant voltage with respect to a potential of another end of the first resistor serving as a reference potential being applied to another end of the series circuit, the method including the steps, executed by a computer, of: obtaining a voltage value of a voltage at the connection node between the upstream switch and the load, or a voltage value of a voltage at the connection node between the load and the downstream switch; and detecting any failure of the upstream switch, the downstream switch, and the load based on the obtained voltage value.

According to the above-described aspect, if a short circuit failure occurs in the upstream switch, it is possible to stop power supply to the load by turning off the downstream switch. The computer detects a failure in the upstream switch, the downstream switch, or the load, based on the voltage value of a voltage at the connection node between the load and the downstream switch, or a voltage value of a voltage at the connection node between the upstream switch and the load.

The following describes specific examples of a power source system according to the embodiments of the present disclosure with reference to the drawings. Note that the present disclosure is not limited to the examples but is defined by the claims, and all modifications within the meaning and scope equivalent to the claims are intended to be included.

### Embodiment 1

### Configuration of Power Source System 1

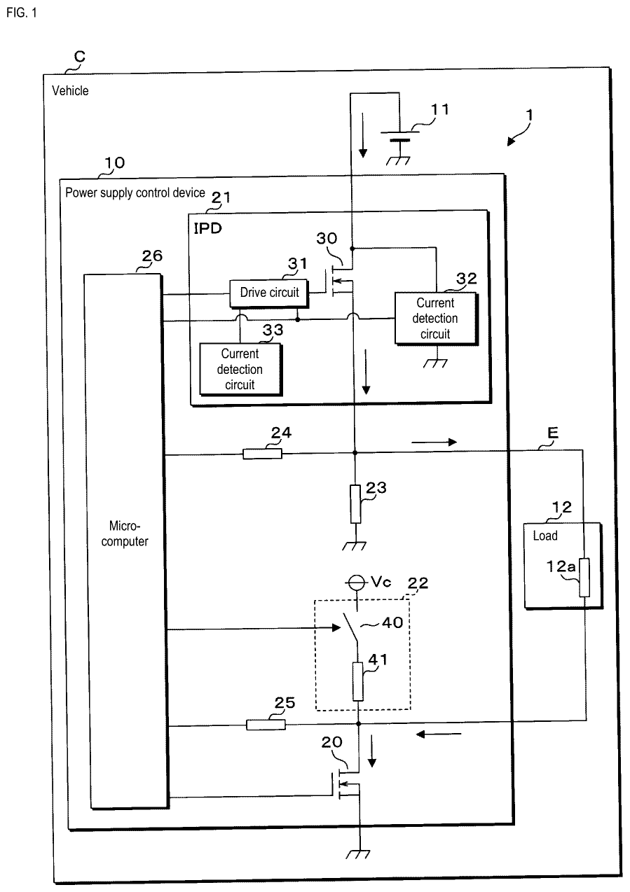

FIG. 1 is a block diagram illustrating a configuration of the main part of a power source system 1 according to Embodiment 1. The power source system 1 is installed in a vehicle C. The power source system 1 includes a power supply control device 10, a DC power source 11, and a load 12. The power supply control device 10 includes a downstream switch 20 and an upstream switch 30. The upstream switch 30 and the downstream switch 20 are semiconductor switches, specifically N-channel field effect transistors (FETs). The DC power source 11 is, for example, a battery. The load 12 is electric equipment and includes a load resistor 12a.

The negative terminal of the DC power source 11 is grounded. Grounding is realized by connecting the negative terminal to the body of the vehicle C. The positive terminal of the DC power source 11 is connected to the drain of the upstream switch 30. The source of the upstream switch 30 is connected to one end of the load resistor 12a of the load 12. Another end of the load resistor 12a is connected to the drain of the downstream switch 20. The source of the downstream switch 20 is grounded.

When both the upstream switch 30 and the downstream switch 20 are in the on state, the resistance value between the corresponding drain and source is sufficiently small. Therefore, a current can flow through the drain and the source. When both the upstream switch 30 and the downstream switch 20 are in the off state, the resistance value between the corresponding drain and source is sufficiently large. Therefore, no current can flow through the drain and the source.

The power supply control device 10 switches the upstream switch 30 and the downstream switch 20 from off to on. When the upstream switch 30 and the downstream switch 20 are on, a current flows from the positive terminal of the DC power source 11 to the upstream switch 30, the load resistor 12a, the downstream switch 20, and the negative terminal of the DC power source 11 in this order, as indicated by arrows. Accordingly, on a current path E for a current flowing through the load resistor 12a of the load 12, the upstream switch 30 is disposed upstream of the load resistor 12a. On the current path E, the downstream switch 20 is disposed downstream of the load resistor 12a. A current flows from the positive terminal of the DC power source 11 to the negative terminal of the DC power source 11 through the current path E.

When a current flows through the load resistor 12a, power is supplied to the load 12. If the power supplied to the load 12 is greater than or equal to a predetermined power, the load 12 operates. If the power supplied to the load 12 is less than the predetermined power, the load 12 is stopped. When the power supply control device 10 switches the upstream switch 30 and the downstream switch 20 from off to on, the DC power source 11 supplies the load 12 with a power that is greater than or equal to the predetermined power. As a result, the load 12 operates.

If at least one of the upstream switch 30 and the downstream switch 20 is off, the DC power source 11 does not supply power to the load 12. Accordingly, when at least one of the upstream switch 30 and the downstream switch 20 is off, the power supplied to the load 12 is less than the predetermined power, and the load 12 is stopped.

The power supply control device 10 switches the upstream switch 30 and the downstream switch 20 from on to off With this, the load 12 stops operating.

As described above, the power supply control device 10 controls the power supply from the DC power source 11 to the load 12 by turning the upstream switch 30 and the downstream switch 20 on or off.

### Configuration of Power Supply Control Device 10

The power supply control device 10 includes, in addition to the downstream switch 20, an IPD 21, a series circuit 22, a first resistor 23, an upstream resistor 24, a downstream resistor 25, and a microcomputer 26. IPD is an abbreviation for Intelligent Power Device. The upstream switch 30 is included in the IPD 21. The IPD 21 includes, in addition to the upstream switch 30, a drive circuit 31, a current detection circuit 32, and a temperature detection circuit 33. The series circuit 22 includes a connection switch 40 and a second resistor 41.

In the series circuit 22, the connection switch 40 is connected in series to the second resistor 41. Accordingly, one end of the connection switch 40 is connected to one end of the second resistor 41. One end of the series circuit 22 is connected to a connection node between the load resistor 12a and the downstream switch 20. A constant voltage with respect to a ground potential serving as a reference potential is applied to the other end of the series circuit 22. Hereinafter, the voltage value of the constant voltage is referred to as “constant voltage value”. In FIG. 1, the constant voltage value is denoted by Vc. The constant voltage is generated by, for example, a regulator stepping down the voltage between the two ends of the DC power source 11. The constant voltage value Vc is lower than the value of the voltage between the two ends of the DC power source 11.

In the example of FIG. 1, the constant voltage is applied to the other end of the connection switch 40. The other end of the second resistor 41 is connected to the connection node between the load resistor 12a and the downstream switch 20. However, the constant voltage may also be applied to the other end of the second resistor 41. In this case, the other end of the connection switch 40 is connected to the connection node between the load resistor 12a and the downstream switch 20.

In the IPD 21, the gate of the upstream switch 30 is connected to the drive circuit 31. The drive circuit 31 is further connected to the microcomputer 26. The drain of the upstream switch 30 is connected to, in addition to the positive terminal of the DC power source 11, the current detection circuit 32. The current detection circuit 32 is grounded. The current detection circuit 32 is further connected to the microcomputer 26 and the drive circuit 31. The drive circuit 31 is further connected to the temperature detection circuit 33.

One end of the first resistor 23 and one end of the upstream resistor 24 are connected to a connection node between the upstream switch 30 of the IPD 21 and the load resistor 12a of the load 12. The other end of the first resistor 23 is grounded. The other end of the upstream resistor 24 is connected to the microcomputer 26. The connection node between the load resistor 12a and the downstream switch 20 is connected to, in addition to the series circuit 22, one end of the downstream resistor 25. The other end of the downstream resistor 25 is connected to the microcomputer 26.

When, for each of the upstream switch 30 and the downstream switch 20, the voltage value of the gate with respect to the potential of the source serving as a reference potential is greater than or equal to a constant voltage value, the corresponding switch is in the on state. When, for each of the upstream switch 30 and the downstream switch 20, the voltage value of the gate with respect to the potential of the source serving as a reference potential is less than the constant voltage value, the corresponding switch is in the off state.

The microcomputer 26 outputs a high-level voltage or a low-level voltage to the drive circuit 31. When the microcomputer 26 switches the voltage output to the drive circuit 31 from the low-level voltage to the high-level voltage, the drive circuit 31 steps up the voltage of the gate of the upstream switch 30 with respect to the ground potential serving as a reference potential. With this, the voltage value of the gate of the upstream switch 30 with respect to the potential of the source serving as a reference potential increases to a voltage value that is greater than or equal to the constant voltage value, and the upstream switch 30 is switched from off to on.

When the microcomputer 26 switches the voltage output to the drive circuit 31 from the high-level voltage to the low-level voltage, the drive circuit 31 steps down the voltage of the gate of the upstream switch 30 with respect to the ground potential serving as a reference potential. With this, the voltage value of the gate of the upstream switch 30 with respect to the potential of the source serving as a reference potential decreases to a voltage value less than the constant voltage value, and the upstream switch 30 is switched from on to off.

In the above-described manner, the drive circuit 31 turns the upstream switch 30 on or off depending on the voltage input from the microcomputer 26.

The microcomputer 26 also outputs a low-level voltage or a high-level voltage to the gate of the downstream switch 20. The potential of the source of the downstream switch 20 is the ground potential. When the microcomputer 26 outputs the low-level voltage to the gate of the downstream switch 20, the voltage value of the gate of the downstream switch 20 with respect to the ground potential serving as a reference potential is less than the constant voltage value, and the downstream switch 20 is off.

When the microcomputer 26 switches the voltage output to the downstream switch 20 from the low-level voltage to the high-level voltage, the voltage value of the gate of the downstream switch 20 with respect to the ground potential serving as a reference potential increases to a voltage value greater than or equal to the constant voltage value, and the downstream switch 20 is switched from off to on. When the microcomputer 26 switches the voltage output to the downstream switch 20 from the high-level voltage to the low-level voltage, the voltage value of the gate of the downstream switch 20 with respect to the ground potential serving as a reference potential decreases to a voltage value less than the constant voltage value, and the downstream switch 20 is switched from on to off.

In the above-described manner, the microcomputer 26 switches the voltage output to the gate of the downstream switch 20 to the low-level voltage or the high-level voltage to turn the downstream switch 20 on or off. The microcomputer 26 controls the state of the upstream switch 30 by switching the voltages to be output to the gates of the drive circuit 31 and the downstream switch 20 to the low-level voltage or the high-level voltage.

The microcomputer 26 switches the upstream switch 30 and the downstream switch 20 from off to on. When the upstream switch 30 and the downstream switch 20 are on, a current flows, as described above, from the positive terminal of the DC power source 11 to the upstream switch 30, the load resistor 12a, the downstream switch 20, and the negative terminal of the DC power source 11 in this order. When the upstream switch 30 is on, a current flows from the positive terminal of the DC power source 11 to the upstream switch 30, the first resistor 23, and the negative terminal of the DC power source 11 in this order.

The resistance value of the first resistor 23 is sufficiently larger than the resistance value of the load resistor 12a of the load 12. Accordingly, when the upstream switch 30 and the downstream switch 20 are on, almost the entire current that has passed through the upstream switch 30 flows through the load resistor 12a.

The current detection circuit 32 detects the current value of a current flowing through the upstream switch 30. Hereinafter, the current value detected by the current detection circuit 32 is referred to as “detected current value”. The current detection circuit 32 outputs analog current information indicating the detected current value to the microcomputer 26 and the drive circuit 31.

The temperature detection circuit 33 detects the temperature of the upstream switch 30. Hereinafter, the temperature detected by the temperature detection circuit 33 is referred to as “detected temperature”. The temperature detection circuit 33 outputs temperature information indicating the detected temperature to the drive circuit 31.

If the detected current value is less than a certain reference current value and the detected temperature is less than a certain reference temperature, the drive circuit 31 turns, as described above, the upstream switch 30 on or off depending on the voltage input from the microcomputer 26. If the detected current value has increased to a current value greater than or equal to the reference current value, the drive circuit 31 forcibly switches the upstream switch 30 from on to off regardless of the voltage input from the microcomputer 26. If the detected temperature has increased to a temperature greater than or equal to the reference temperature, the drive circuit 31 forcibly switches the upstream switch 30 from on to off regardless of the voltage input from the microcomputer 26. If a predetermined condition is satisfied, the drive circuit 31 cancels the forcible turning off of the upstream switch 30.

The microcomputer 26 turns the connection switch 40 of the series circuit 22 on or off. When the connection switch 40 is on, the resistance value between the two ends of the connection switch 40 is sufficiently small. Therefore, a current can flow through the connection switch 40. When the connection switch 40 is off, the resistance value between the two ends of the connection switch 40 is sufficiently large. Therefore, no current flows through the connection switch 40.

Hereinafter, the value of the voltage at the connection node between the upstream switch 30 and the load resistor 12a is referred to as “first voltage value”. The value of a voltage at the connection node between the load resistor 12a and the downstream switch 20 is referred to as “second voltage value”. The reference potential for the first voltage value and the second voltage value is the ground potential. An analog first voltage value is input to the microcomputer 26 via the upstream resistor 24. An analog second voltage value is input to the microcomputer 26 via the downstream resistor 25. The microcomputer 26 detects a failure of the upstream switch 30, the downstream switch 20, and the load 12, based on the first voltage value, the second voltage value, and the detected current value.

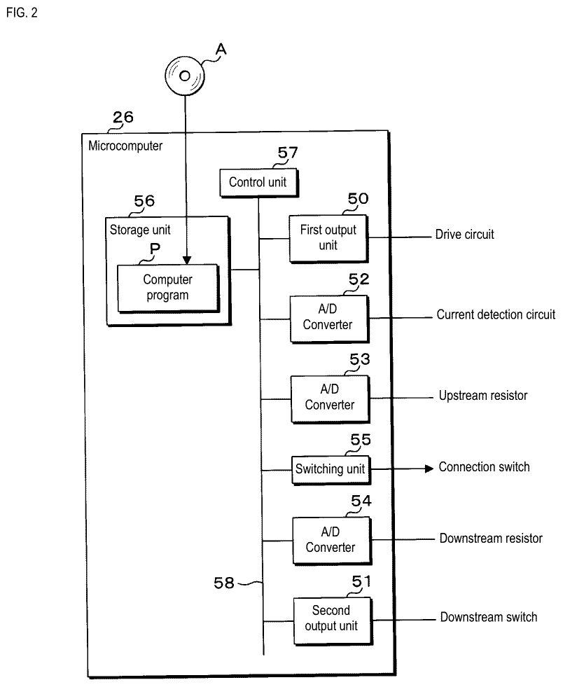

FIG. 2 is a block diagram illustrating a configuration of the main part of the microcomputer 26. The microcomputer 26 includes a first output unit 50, a second output unit 51, three A/D converters 52, 53, and 54, a switching unit 55, a storage unit 56, and a control unit 57. These units are connected to an internal bus 58. The first output unit 50 is further connected to the drive circuit 31. The second output unit 51 is further connected to the gate of the downstream switch 20. The A/D converters 52, 53, and 54 are further connected to the current detection circuit 32, the other end of the upstream resistor 24, and the other end of the downstream resistor 25, respectively.

The first output unit 50 outputs the high-level voltage or the low-level voltage to the drive circuit 31. The voltage output to the drive circuit 31 by the microcomputer 26 is a voltage output to the drive circuit 31 by the first output unit 50. The control unit 57 instructs the first output unit 50 to turn on the upstream switch 30. In response thereto, the first output unit 50 switches the voltage output to the drive circuit 31 from the low-level voltage to the high-level voltage. As a result, the drive circuit 31 switches the upstream switch 30 from off to on.

The control unit 57 instructs the first output unit 50 to turn off the upstream switch 30. In response thereto, the first output unit 50 switches the voltage output to the drive circuit 31 from the high-level voltage to the low-level voltage. As a result, the drive circuit 31 switches the upstream switch 30 from on to off.

The second output unit 51 outputs the high-level voltage or the low-level voltage to the gate of the downstream switch 20. The voltage output to the gate of the downstream switch 20 by the microcomputer 26 is a voltage that is output to the gate of the downstream switch 20 by the first output unit 50. The control unit 57 instructs the second output unit 51 to turn on the downstream switch 20. In response thereto, the second output unit 51 switches the voltage output to the gate of the downstream switch 20 from the low-level voltage to the high-level voltage. As a result, the downstream switch 20 is switched from off to on.

The control unit 57 instructs the second output unit 51 to turn off the downstream switch 20. In response thereto, the second output unit 51 switches the voltage output to the gate of the downstream switch 20 from the high-level voltage to the low-level voltage. As a result, the downstream switch 20 is switched from on to off.

The current detection circuit 32 outputs analog current information indicating the detected current value to the A/D converter 52. The A/D converter 52 converts the analog current information into digital current information. The control unit 57 obtains the digital current information converted by the A/D converter 52. An analog first voltage value is input to the A/D converter 53 via the upstream resistor 24. The A/D converter 53 converts the analog first voltage value into a digital first voltage value. The control unit 57 obtains the digital first voltage value converted by the A/D converter 53.

An analog second voltage value is input to the A/D converter 54 via the downstream resistor 25. The A/D converter 54 converts the analog second voltage value into a digital second voltage value. The control unit 57 obtains the digital second voltage value converted by the A/D converter 54. The switching unit 55 turns the connection switch 40 on or off in accordance with an instruction of the control unit 57.

The storage unit 56 is, for example, a nonvolatile memory. The storage unit 56 has stored therein a computer program P. The control unit 57 includes a processing element for executing processing such as a central processing unit (CPU), for example. The control unit 57 functions as a processing unit. By executing the computer program P, the processing element of the control unit 57 executes power supply control processing for controlling the power supply from the DC power source 11 to the load 12.

Note that the computer program P may be provided to the microcomputer 26 with the use of a non-transitory storage medium A in which the computer program P is readably stored. The storage medium A is, for example, a portable memory. Examples of a portable memory include a CD-ROM, a universal serial bus (USB) memory, a SD card, a micro SD card, and a compact flash (registered trademark). When the storage medium A is a portable memory, the processing element of the control unit 57 may read the computer program P from the storage medium A using a not-shown reading device. The read computer program P is written into the storage unit 56. Furthermore, the computer program P may also be provided to the microcomputer 26 by a not-shown communication unit of the microcomputer 26 communicating with an external device. In this case, the processing element of the control unit 57 obtains the computer program P via the communication unit. The obtained computer program P is written into the storage unit 56.

The number of processing elements included in the control unit 57 is not limited to one, and may be two or more. If the control unit 57 includes a plurality of processing elements, the plurality of processing elements may cooperate with each other to execute power supply control processing.

In the power supply control processing, the control unit 57 diagnoses any failure in the upstream switch 30, the downstream switch 20, and the load 12 using a plurality of thresholds set in advance.

### Description of Plurality of Thresholds

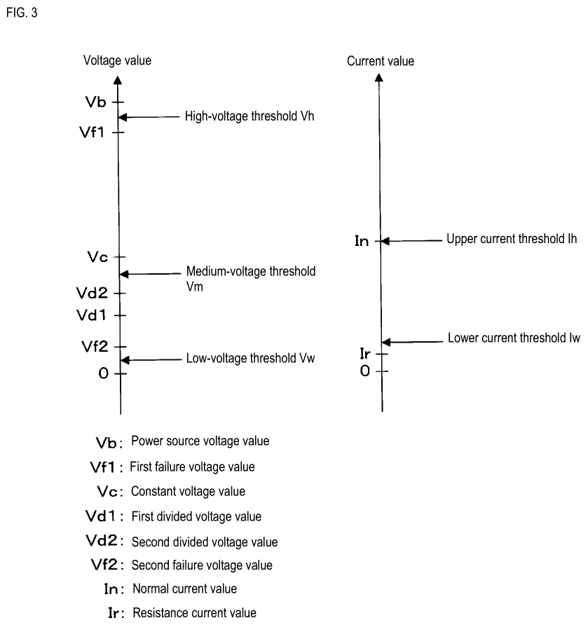

FIG. 3 is a diagram illustrating a plurality of thresholds. With respect to voltage values, a high-voltage threshold Vh, a medium-voltage threshold Vm, and a low-voltage threshold Vw are set in advance. In FIG. 3, Vb denotes the value of a voltage between the two ends of the DC power source 11. Hereinafter, the value of a voltage between the two ends of the DC power source 11 is referred to as “power source voltage value”.

One of the failures of the upstream switch 30 and the downstream switch 20 is a half-on failure. If a half-on failure occurs in the upstream switch 30 or the downstream switch 20, the resistance value between the drain and the source is maintained as a halfway value regardless of the voltage value of the gate. The halfway value is neither a sufficiently large value nor a sufficiently small value. A half-on failure in the upstream switch 30 or the downstream switch 20 is a failure regarding the resistance of the upstream switch 30 or the downstream switch 20.

As described above, the resistance value of the first resistor 23 is sufficiently larger than the resistance value of the load resistor 12a. Therefore, if a half-on failure occurs in the upstream switch 30 while the downstream switch 20 is on, the first voltage value substantially matches the voltage value of a voltage obtained by the upstream switch 30 and the load resistor 12a dividing the voltage between the two ends of the DC power source 11. The first voltage value when a half-on failure of the upstream switch 30 has occurred while the downstream switch 20 is on is referred to as “first failure voltage value”. Vf1 denotes the first failure voltage value. The first failure voltage value Vf1 is less than the power source voltage value Vb.

As described above, Vc denotes the constant voltage value. The constant voltage value Vc is the voltage value of the constant voltage applied to the series circuit 22. The power source voltage value Vb is 12 V for example. The constant voltage value is 3.3 V 5 V, or the like, for example. The constant voltage value Vc is less than the first failure voltage value Vf1.

When the upstream switch 30, the downstream switch 20, and the connection switch 40 are respectively off, off, and on, a second resistor circuit including the second resistor 41 and the load resistor 12a, and the first resistor 23 divide the constant voltage. The voltage value of a voltage obtained by the second resistor circuit and the first resistor 23 dividing the constant voltage is referred to as “first divided voltage value”. Vd1 denotes the first divided voltage value. The first divided voltage value Vd1 is the first voltage value when the upstream switch 30, the downstream switch 20, and the connection switch 40 are respectively off, off, and on.

When the upstream switch 30, the downstream switch 20, and the connection switch 40 are respectively off, off, and on, the second resistor 41, and a first resistor circuit including the load resistor 12a and the first resistor 23 divide the constant voltage. The voltage value of a voltage obtained by the second resistor 41 and the first resistor circuit dividing the constant voltage is referred to as “second divided voltage value”. Vd2 denotes the second divided voltage value. The second divided voltage value Vd2 is the second voltage value when the upstream switch 30, the downstream switch 20, and the connection switch 40 are respectively off, off, and on. The second divided voltage value Vd2 is less than the constant voltage value Vc. The first divided voltage value Vd1 is less than the second divided voltage value Vd2.

The resistance values of the first resistor 23 and the second resistor 41 are sufficiently larger than the resistance value of the load resistor 12a. Accordingly, the first divided voltage value Vd1 and the second divided voltage value Vd2 substantially match the voltage value of a voltage obtained by the second resistor 41 and the first resistor 23 dividing the constant voltage.

As described above, the resistance value of the first resistor 23 is sufficiently larger than the resistance value of the load resistor 12a. Therefore, if a half-on failure occurs in the downstream switch 20 while the upstream switch 30 is on, the second voltage value substantially matches the voltage value of a voltage obtained by the upstream switch 30 and the load resistor 12a dividing the voltage between the two ends of the DC power source 11. The second voltage value when a half-on failure of the upstream switch 30 has occurred while the downstream switch 20 is on is referred to as “second failure voltage value”. Vf2 denotes the second failure voltage value. The second failure voltage value Vf2 is less than the first divided voltage value Vd1 and exceeds 0 V.

The high-voltage threshold Vh is a voltage value that exceeds the first failure voltage value Vf1 and is less than the power source voltage value Vb. The medium-voltage threshold Vm is a voltage value that exceeds the second divided voltage value Vd2 and is less than the constant voltage value Vc. The low-voltage threshold Vw is a voltage value that exceeds 0 V and is less than the second failure voltage value Vf2.

With respect to current values, an upper current threshold Ih and a lower current threshold Iw are set in advance. The current value of a current flowing through the upstream switch 30 when the load 12 is in a normal state and the upstream switch 30 and the downstream switch 20 are on is referred to as “normal current value”. In FIG. 3, In is a normal current value. The current value of a current flowing through the upstream switch 30 when the load 12 is in a normal state, and the upstream switch 30, the downstream switch 20, and the connection switch 40 are respectively on, off, and off is referred to as “resistance current value”. In FIG. 3, Ir is the resistance current value.

The resistance current value Ir is the current value of a current flowing from the positive terminal of the DC power source 11 to the upstream switch 30, the first resistor 23, and to the negative terminal of the DC power source 11 in this order. As described above, the resistance value of the load resistor 12a is less than the resistance value of the first resistor 23. Therefore, the resistance current value Ir is less than the normal current value In. The upper current threshold Ih is the normal current value In. The lower current threshold Iw exceeds the resistance current value Ir, and is less than or equal to the normal current value In.

Failure Diagnosis when Load 12 is Stopped

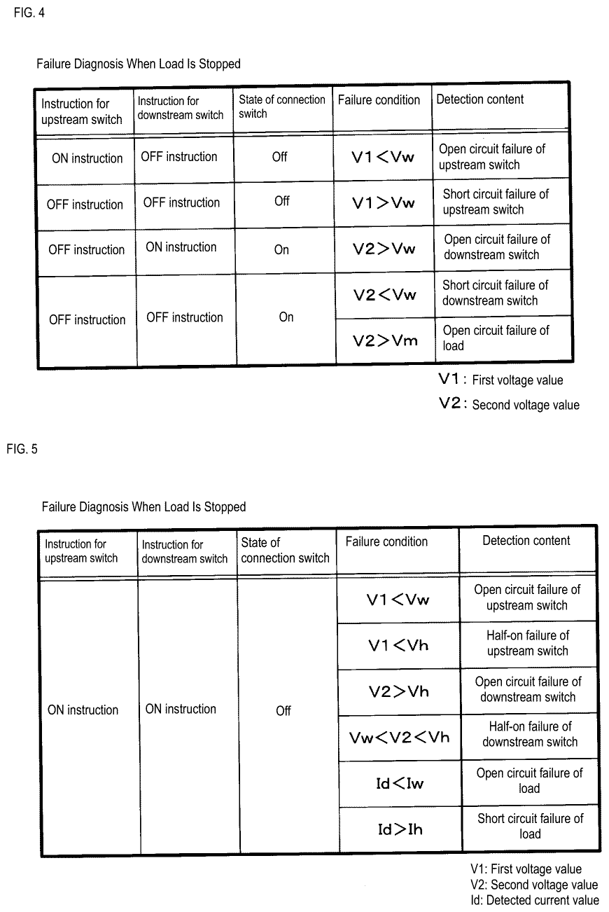

FIG. 4 is a table illustrating failure diagnosis when the load 12 is stopped. FIG. 4 shows instructions for the upstream switch 30, instructions for the downstream switch 20, states of the connection switch 40, failure conditions, and detection content. The instructions for the upstream switch 30 are the instructions that the control unit 57 of the microcomputer 26 gives to the first output unit 50. The instructions for the downstream switch 20 are instructions that the control unit 57 gives to the second output unit 51. “ON instruction” refers to an instruction to perform turning on. “OFF instruction” refers to an instruction to perform turning off Failure conditions are conditions to be satisfied if a failure occurs. Detection content indicates failures detected by the control unit 57.

V1 and V2 respectively denote the first voltage value and the second voltage value. As described above, the first voltage value V1 is the value of a voltage at the connection node between the upstream switch 30 and the load resistor 12a. The second voltage value V2 is the value of a voltage at the connection node between the load resistor 12a and the downstream switch 20.

The control unit 57 performs failure diagnosis when an instruction to turn off at least one of the upstream switch 30 and the downstream switch 20 has been given. Therefore, the load resistor 12a is not supplied with a power greater than or equal to the predetermined power, and the load 12 is stopped.

The control unit 57 gives an instruction to turn on the upstream switch 30, gives an instruction to turn off the downstream switch 20, and obtains the first voltage value V1 from the A/D converter 53 while the connection switch 40 is off. The control unit 57 detects an open circuit failure of the upstream switch 30 based on the obtained first voltage value V1. An open circuit failure of the switch is a phenomenon in which the resistance value between the two ends of the switch is sufficiently large although an instruction to turn on the switch has been given.

When the upstream switch 30, the downstream switch 20, and the connection switch 40 are respectively on, off, and off, a current flows from the positive terminal of the DC power source 11 through the upstream switch 30 and the first resistor 23 in this order. No current flows through the load resistor 12a. Accordingly, when the upstream switch 30, the downstream switch 20, and the connection switch 40 are respectively on, off, and off, the first voltage value V1 and the second voltage value V2 are equal to the power source voltage value Vb, and are greater than or equal to the low-voltage threshold Vw. If an open circuit failure occurs in the upstream switch 30, no current will flow through the first resistor 23 and no current flows through the load resistor 12a. Therefore, the first voltage value V1 and the second voltage value V2 are 0 V and are less than the low-voltage threshold Vw.

As a result, the control unit 57 detects an open circuit failure of the upstream switch 30 when the first voltage value V1 obtained from the A/D converter 53 is less than the low-voltage threshold Vw. Note that the control unit 57 may also detect an open circuit failure of the upstream switch 30 when the second voltage value V2 obtained from the A/D converter 54 is less than the low-voltage threshold Vw. In this case, the control unit 57 gives an instruction to turn on the upstream switch 30, gives an instruction to turn off the downstream switch 20, and obtains the second voltage value V2 from the A/D converter 54 while the connection switch 40 is off A voltage threshold for use in detecting an open circuit failure of the upstream switch 30 need only exceed 0 V and be less than or equal to the power source voltage value Vb.

The control unit 57 gives an instruction to turn off the upstream switch 30 and the downstream switch 20, and obtains the first voltage value V1 from the A/D converter 53 while the connection switch 40 is off. The control unit 57 detects a short circuit failure of the upstream switch 30 based on the obtained first voltage value V1. A short circuit failure of the switch is a phenomenon in which the resistance value between the two ends of the switch is very small although an instruction to turn off the switch has been given.

When all of the upstream switch 30, the downstream switch 20, and the connection switch 40 are off, no current flows through the first resistor 23 and no current flows through the load resistor 12a. Accordingly when all of the upstream switch 30, the downstream switch 20, and the connection switch 40 are off, the first voltage value V1 and the second voltage value V2 are 0 V and are less than or equal to the low-voltage threshold Vw. If a short circuit failure occurs in the upstream switch 30, a current flows from the positive terminal of the DC power source 11 to the upstream switch 30 and the first resistor 23 in this order, and no current flows through the load resistor 12a. Therefore, the first voltage value V1 and the second voltage value V2 are equal to the power source voltage value Vb, and exceed the low-voltage threshold Vw.

As a result, the control unit 57 detects a short circuit failure of the upstream switch 30 when the first voltage value V1 obtained from the A/D converter 53 exceeds the low-voltage threshold Vw. Note that the control unit 57 may also detect a short circuit failure of the upstream switch 30 when the second voltage value V2 obtained from the A/D converter 54 exceeds the low-voltage threshold Vw. In this case, the control unit 57 gives an instruction to turn off the upstream switch 30 and the downstream switch 20, and obtains the second voltage value V2 from the A/D converter 54 while the connection switch 40 is off A second voltage threshold for use in detecting a short circuit failure of the upstream switch 30 need only be 0 V or more and be less than the power source voltage value Vb.

The control unit 57 gives an instruction to turn off the upstream switch 30, gives an instruction to turn on the downstream switch 20, and obtains the second voltage value V2 from the A/D converter 54 while the connection switch 40 is on. The control unit 57 detects an open circuit failure of the downstream switch 20 based on the obtained second voltage value V2.

When the upstream switch 30, the downstream switch 20, and the connection switch 40 are respectively off, on, and on, a current flows through the connection switch 40, the second resistor 41, and the downstream switch 20 in this order, and no current flows through the first resistor 23. Accordingly when the upstream switch 30, the downstream switch 20, and the connection switch 40 are respectively off, on, and on, the first voltage value V1 and the second voltage value V2 are 0 V, and are less than the low-voltage threshold Vw.

If an open circuit failure occurs in the downstream switch 20, a current flows through the second resistor 41, the load resistor 12a, and the first resistor 23 in this order. The second resistor circuit and the first resistor 23 divide the constant voltage. The second resistor 41 and the first resistor circuit divide the constant voltage. Accordingly, the first voltage value V1 and the second voltage value V2 are respectively equal to the first divided voltage value Vd1 and the second divided voltage value Vd2. Therefore, the first voltage value V1 and the second voltage value V2 exceed the low-voltage threshold Vw.

As a result, the control unit 57 detects an open circuit failure of the downstream switch 20 when the second voltage value V2 obtained from the A/D converter 54 exceeds the low-voltage threshold Vw. Note that the control unit 57 may also detect an open circuit failure of the downstream switch 20 when the first voltage value V1 obtained from the A/D converter 53 exceeds the low-voltage threshold Vw. In this case, the control unit 57 gives an instruction to turn off the upstream switch 30, gives an instruction to turn on the downstream switch 20, and obtains the first voltage value V1 from the A/D converter 53 while the connection switch 40 is on. With respect to the first voltage value V1, a third voltage threshold for use in detecting an open circuit failure of the downstream switch 20 need only be 0 V or more and be less than the first divided voltage value Vd1. With respect to the second voltage value V2, the third voltage threshold for use in detecting an open circuit failure of the downstream switch 20 need only be 0 V or more and be less than the second divided voltage value Vd2.

As described above, the first divided voltage value Vd1 is the first voltage value V1 obtained by the control unit 57 from the A/D converter 53 when the upstream switch 30, the downstream switch 20, and the connection switch 40 are respectively off, off, and on. The second divided voltage value Vd2 is the second voltage value V2 obtained by the control unit 57 from the A/D converter 54 when the upstream switch 30, the downstream switch 20, and the connection switch 40 are respectively off, off, and on.

When a current flows through the second resistor 41, the load resistor 12a, and the first resistor 23 in this order, power is supplied to the load 12. However, since the constant voltage value Vc is small, the power supplied to the load 12 is less than a predetermined power. Accordingly, when a current flows through the second resistor 41, the load resistor 12a, and the first resistor 23 in this order, the load 12 does not operate.

The control unit 57 gives instructions to turn off the upstream switch 30 and the downstream switch 20, and obtains the second voltage value V2 from the A/D converter 54 while the connection switch 40 is on. The control unit 57 detects a short circuit failure of the downstream switch 20 based on the obtained second voltage value V2.

As described above, when the upstream switch 30, the downstream switch 20, and the connection switch 40 are respectively off, off, and on, the first voltage value V1 and the second voltage value V2 are respectively equal to the first divided voltage value Vd1 and the second divided voltage value Vd2. Accordingly when the upstream switch 30, the downstream switch 20, and the connection switch 40 are respectively off, off, and on, the first voltage value V1 and the second voltage value V2 are greater than or equal to the low-voltage threshold Vw. If a short circuit failure occurs in the downstream switch 20, a current flows through the connection switch 40, the second resistor 41, and the downstream switch 20 in this order, and no current flows through the load resistor 12a. Therefore, the first voltage value V1 and the second voltage value V2 are 0 V and are less than the low-voltage threshold Vw.

As a result, the control unit 57 detects a short circuit failure of the downstream switch 20 when the second voltage value V2 obtained from the A/D converter 54 is less than the low-voltage threshold Vw. Note that the control unit 57 may also detect a short circuit failure of the downstream switch 20 when the first voltage value V1 obtained from the A/D converter 53 is less than the low-voltage threshold Vw. In this case, the control unit 57 gives instructions to turn off the upstream switch 30 and the downstream switch 20, and obtains the first voltage value V1 from the A/D converter 53 while the connection switch 40 is on. With respect to the first voltage value V1, a fourth voltage threshold for use in detecting a short circuit failure of the downstream switch 20 need only exceed 0 V and be less than or equal to the first divided voltage value Vd1. With respect to the second voltage value V2, the fourth voltage threshold for use in detecting a short circuit failure of the downstream switch 20 need only exceed 0 V and be less than or equal to the second divided voltage value Vd2.

The control unit 57 gives instructions to turn off the upstream switch 30 and the downstream switch 20, and obtains the second voltage value V2 from the A/D converter 54 while the connection switch 40 is on. The control unit 57 detects an open circuit failure of the load 12 based on the obtained second voltage value V2. An open circuit failure of the load 12 is a phenomenon in which the resistance value between the two ends of the load 12, that is, the resistance value between the two ends of the load resistor 12a is extremely large.

As described above, when the upstream switch 30, the downstream switch 20, and the connection switch 40 are respectively off, off, and on, and the load 12 is in a normal state, the second voltage value V2 is the second divided voltage value Vd2 and is less than or equal to the medium-voltage threshold Vm. If an open circuit failure occurs in the load 12, no current flows through the second resistor 41 while the connection switch 40 is on. Therefore, the second voltage value V2 is the constant voltage value Vc and exceeds the medium-voltage threshold Vm.

As a result, the control unit 57 detects an open circuit failure of the load 12 when the second voltage value V2 obtained from the A/D converter 54 exceeds the medium-voltage threshold Vm. Note that a fifth voltage threshold for use in detecting an open circuit failure of the load 12 need only exceed the second divided voltage value Vd2 and be less than the constant voltage value Vc.

Failure Diagnosis when Load 12 is Operating

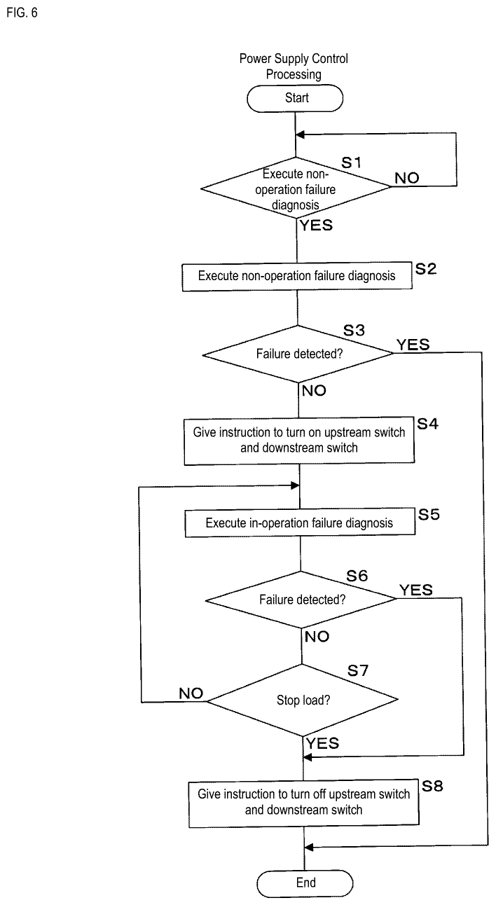

FIG. 5 is a table illustrating failure diagnosis when a load 12 is operating. Similar to FIG. 4, FIG. 5 shows instructions for the upstream switch 30, instructions for the downstream switch 20, states of the connection switch 40, failure conditions, and detection content. Id denotes a detected current value. As described above, the detected current value is the current value of a current flowing through the upstream switch 30.

The control unit 57 gives instructions to turn on the upstream switch 30 and the downstream switch 20, and obtains the first voltage value V1 from the A/D converter 53 while the connection switch 40 is off. The control unit 57 detects an open circuit failure of the upstream switch 30 based on the obtained first voltage value V1.

As described above, when the upstream switch 30, the downstream switch 20, and the connection switch 40 are respectively on, on and off, a current flows from the positive terminal of the DC power source 11 to the upstream switch 30, the load resistor 12a, the downstream switch 20, and the negative terminal of the DC power source 11 in this order. At this time, the DC power source 11 supplies the load resistor 12a with a power greater than or equal to the predetermined power, and thus the load 12 is operating. As described above, when the upstream switch 30 is on, a current flows from the positive terminal of the DC power source 11 to the upstream switch 30, the first resistor 23, and the negative terminal of the DC power source 11.

When the upstream switch 30, the downstream switch 20, and the connection switch 40 are respectively on, on, and off, the first voltage value V1 is the power source voltage value Vb, and is greater than or equal to the low-voltage threshold Vw. If an open circuit failure occurs in the upstream switch 30, no current flows through the first resistor 23. Therefore, the first voltage value V1 is 0 V and is less than the low-voltage threshold Vw. As a result, the control unit 57 detects an open circuit failure of the upstream switch 30 when the first voltage value V1 obtained from the A/D converter 53 is less than the low-voltage threshold Vw. Note that a sixth voltage threshold for use in detecting an open circuit failure of the upstream switch 30 need only exceed 0 V and be less than or equal to the power source voltage value Vb.

The control unit 57 gives instructions to turn on the upstream switch 30 and the downstream switch 20, and obtains the first voltage value V1 from the A/D converter 53 while the connection switch 40 is off. The control unit 57 detects a half-on failure of the upstream switch 30 based on the obtained first voltage value V1.

When the upstream switch 30, the downstream switch 20, and the connection switch 40 are respectively on, on, and off, the first voltage value V1 is the power source voltage value Vb, and is greater than or equal to the high-voltage threshold Vh. When a half-on failure has occurred in the upstream switch 30, the first voltage value V1 is equal to the first failure voltage value Vf1 and is less than the high-voltage threshold Vh. As a result, the control unit 57 detects a half-on failure of the upstream switch 30 when the first voltage value V1 obtained from the A/D converter 53 is less than the high-voltage threshold Vh. Note that a seventh voltage threshold for use in detecting a half-on failure of the upstream switch 30 need only exceed the first failure voltage value Vf1 and be less than or equal to the power source voltage value Vb.

If a half-on failure occurs in the upstream switch 30 while the downstream switch 20 is on, the heat amount of heat generated by the upstream switch 30 per unit time rapidly increases. With this, the temperature of the upstream switch 30 increases to a temperature greater than or equal to the reference temperature, and the drive circuit 31 forcibly turns off the upstream switch 30 regardless of a voltage input from the first output unit 50 of the microcomputer 26. A half-on failure of the upstream switch 30 is detected by the drive circuit 31 or the control unit 57.

The control unit 57 gives instructions to turn on the upstream switch 30 and the downstream switch 20, and obtains the second voltage value V2 from the A/D converter 54 while the connection switch 40 is off. The control unit 57 detects an open circuit failure of the downstream switch 20 based on the obtained second voltage value V2.

When the upstream switch 30, the downstream switch 20, and the connection switch 40 are respectively on, on, and off, the second voltage value V2 is 0 V, and is less than or equal to the high-voltage threshold Vh. If an open circuit failure occurs in the downstream switch 20, no current flows through the load resistor 12a. Therefore, the first voltage value V1 is the power source voltage value Vb, and exceeds the high-voltage threshold Vh. As a result, the control unit 57 detects an open circuit failure of the downstream switch 20 when the second voltage value V2 obtained from the A/D converter 54 exceeds the high-voltage threshold Vh. Note that an eighth voltage threshold for use in detecting an open circuit failure of the downstream switch 20 need only be 0 V or more and be less than the power source voltage value Vb.

The control unit 57 gives instructions to turn on the upstream switch 30 and the downstream switch 20, and obtains the second voltage value V2 from the A/D converter 54 while the connection switch 40 is off. The control unit 57 detects a half-on failure of the downstream switch 20 based on the obtained second voltage value V2.

When the upstream switch 30, the downstream switch 20, and the connection switch 40 are respectively on, on, and off, the second voltage value V2 is 0 V and is less than or equal to the low-voltage threshold Vw. When a half-on failure has occurred in the downstream switch 20, the second voltage value V2 is the second failure voltage value Vf2, exceeds the low-voltage threshold Vw, and is less than the high-voltage threshold Vh. As a result, the control unit 57 detects a half-on failure of the downstream switch 20 when the second voltage value V2 exceeds the low-voltage threshold Vw and is less than the high-voltage threshold Vh.

Note that the lower voltage threshold for use in detecting a half-on failure of the downstream switch 20 need only be 0 V or more and be less than the second failure voltage value Vf2. The lower voltage threshold corresponds to a ninth voltage threshold. Note that the upper voltage threshold for use in detecting a half-on failure of the downstream switch 20 need only be greater than or equal to the first failure voltage value Vf1 and be less than the power source voltage value Vb.

The control unit 57 gives instructions to turn on the upstream switch 30 and the downstream switch 20, and obtains current information from the A/D converter 52 while the connection switch 40 is off. As described above, current information indicates the detected current value Id, that is, the current value of a current flowing through the upstream switch 30. Obtaining current information corresponds to obtaining the detected current value Id. The control unit 57 detects an open circuit failure of the load 12 based on the detected current value Id indicated by the obtained current information.

When the upstream switch 30, the downstream switch 20, and the connection switch 40 are respectively on, on, and off while the load 12 is in a normal state, the detected current value Id is equal to the normal current value In, and is greater than or equal to the lower current threshold Iw. If an open circuit failure occurs in the load 12, the detected current value Id is the resistance current value Ir, and is less than the lower current threshold Iw. Accordingly, the control unit 57 detects an open circuit failure of the load 12 when the detected current value Id indicated by the current information obtained from the A/D converter 52 is less than the lower current threshold Iw.

The control unit 57 gives instructions to turn on the upstream switch 30 and the downstream switch 20, and obtains current information from the A/D converter 52 while the connection switch 40 is off. The control unit 57 detects a short circuit failure of the load 12 based on the detected current value Id indicated by the obtained current information. The short circuit failure of the load 12 is a phenomenon in which the resistance value between the two ends of the load 12, that is, the resistance value between the two ends of the load resistor 12a is extremely small.

When the upstream switch 30, the downstream switch 20, and the connection switch 40 are respectively on, on, and off while the load 12 is in a normal state, the detected current value Id is the normal current value In, and is less than or equal to the upper current threshold Ih. If a short circuit failure occurs in the load 12, the detected current value Id exceeds the upper current threshold Ih (normal current value In). Accordingly the control unit 57 detects a short circuit failure of the load 12 when the detected current value Id indicated by the current information obtained from the A/D converter 52 exceeds the upper current threshold Ih. The upper current threshold Ih refers to the second current threshold.

When a short circuit failure occurs in the load 12 while the upstream switch 30 and the downstream switch 20 are on, the detected current value Id increases to a current having a reference current value or more, and the drive circuit 31 forcibly turns off the upstream switch 30 regardless of a voltage input from the first output unit 50 of the microcomputer 26. A short circuit failure of the load 12 is detected by the drive circuit 31 or the control unit 57.

### Power Supply Control Processing

FIG. 6 is a flowchart illustrating a procedure of power supply control processing. Hereinafter, failure diagnosis when the load 12 is stopped is referred to as “non-operation failure diagnosis”. Failure diagnosis when the load 12 is operating is referred to as “in-operation failure diagnosis”. The control unit 57 of the microcomputer 26 executes power supply control processing in a state in which instructions to turn off the upstream switch 30, the downstream switch 20, and the connection switch 40 have been given.

In the power supply control processing, the control unit 57 determines whether or not to operate the load 12 (step S1). If it is determined not to operate the load 12 (NO in step S1), the control unit 57 executes step S1 again. The control unit 57 stands by until the timing of operating the load 12 arrives. If it is determined to operate the load 12 (YES in step S1), the control unit 57 executes non-operation failure diagnosis in accordance with the content in FIG. 4 (step S2).

By instructing the switching unit 55 to turn on the connection switch 40, the control unit 57 turns on the connection switch 40. By instructing the switching unit 55 to turn off the connection switch 40, the control unit 57 turns off the connection switch 40. The control unit 57 performs the non-operation failure diagnosis to determine whether or not an open circuit failure of the upstream switch 30, a short circuit failure of the upstream switch 30, an open circuit failure of the downstream switch 20, a short circuit failure of the downstream switch 20, or an open circuit failure of the load 12 is occurring. The control unit 57 ends the non-operation failure diagnosis in a state in which instructions to turn off the upstream switch 30, the downstream switch 20, and the connection switch 40 have been given.

After the execution of step S2, the control unit 57 determines whether or not any failure has been detected in the non-operation failure diagnosis (step S3). If it is determined that no failure has been detected in the non-operation failure diagnosis (NO in step S3), the control unit 57 gives instructions to turn on the upstream switch 30 and the downstream switch 20 to the first output unit 50 and the second output unit 51, respectively (step S4). When the upstream switch 30 and the downstream switch 20 are turned on while the load 12 is in a normal state, the DC power source 11 supplies the load resistor 12a with a power greater than or equal to the predetermined power. With this, the load 12 operates.

After the execution of step S4, the control unit 57 executes in-operation failure diagnosis in accordance with the content in FIG. 5 (step S5). The control unit 57 performs the in-operation failure diagnosis to determine whether or not an open circuit failure of the upstream switch 30, a half-on failure of the upstream switch 30, an open circuit failure of the downstream switch 20, a half-on failure of the downstream switch 20, an open circuit failure of the load 12, or a short circuit failure of the load 12 is occurring. The control unit 57 ends the in-operation failure diagnosis in a state in which instructions to turn on the upstream switch 30 and the downstream switch 20 have been given, and an instruction to turn off the connection switch 40 has been given.

After the execution of step S5, the control unit 57 determines whether or not any failure has been detected in the in-operation failure diagnosis (step S6). If it is determined that no failure has been detected in the in-operation failure diagnosis (NO in step S6), the control unit 57 determines whether or not to stop the operation of the load 12 (step S7). If it is determined not to stop the operation of the load 12 (NO in step S7), the control unit 57 executes step S5 again. The control unit 57 stands by until a failure is detected or the timing of stopping the operation of the load 12 arrives.

If it is determined that a failure has been detected in the in-operation failure diagnosis (YES in step S6), or it is determined to stop the operation of the load 12 (YES in step S7), the control unit 57 gives instructions to turn off the upstream switch 30 and the downstream switch 20 to the first output unit 50 and the second output unit 51, respectively (step S8). When the upstream switch 30 and the downstream switch 20 are turned off, power supply from the DC power source 11 to the load resistor 12a is stopped, and the operation of the load 12 is stopped.

If it is determined that a failure has been detected in the non-operation failure diagnosis (YES in step S3), or after the execution of step S8, the control unit 57 ends the power supply control processing. If no failure is detected after the completion of the power supply control processing, the control unit 57 executes the power supply control processing again. Note that the control unit 57 may also execute the non-operation failure diagnosis after the execution of step S8. In this case, the control unit 57 executes the non-operation failure diagnosis, and then ends the power supply control processing.

As described above, in the power supply control processing, upon detection of a failure in the in-operation failure diagnosis, the control unit 57 gives instructions to turn off the upstream switch 30 and the downstream switch 20. Accordingly, if a short circuit failure occurs in the upstream switch 30, the downstream switch 20 is turned off, and power supply to the load 12 is stopped. Also, the control unit 57 detects any failure in the upstream switch 30, the downstream switch 20, and the load 12, based on the first voltage value V1 or the second voltage value V2.

### Embodiment 2

In Embodiment 1, the drive circuit 31 detects a half-on failure of the upstream switch 30 and a short circuit failure of the load 12. However, the drive circuit 31 does not need to have such a failure detection function.

The following will describe the configurations of Embodiment 2 that are different from those of Embodiment 1. Configurations other than the configurations below are the same as those in Embodiment 1. Accordingly the same reference numerals as those in Embodiment 1 are given to the same configurations as those in Embodiment 1, and descriptions thereof are omitted.

### Configuration of Power Supply Control Device 10

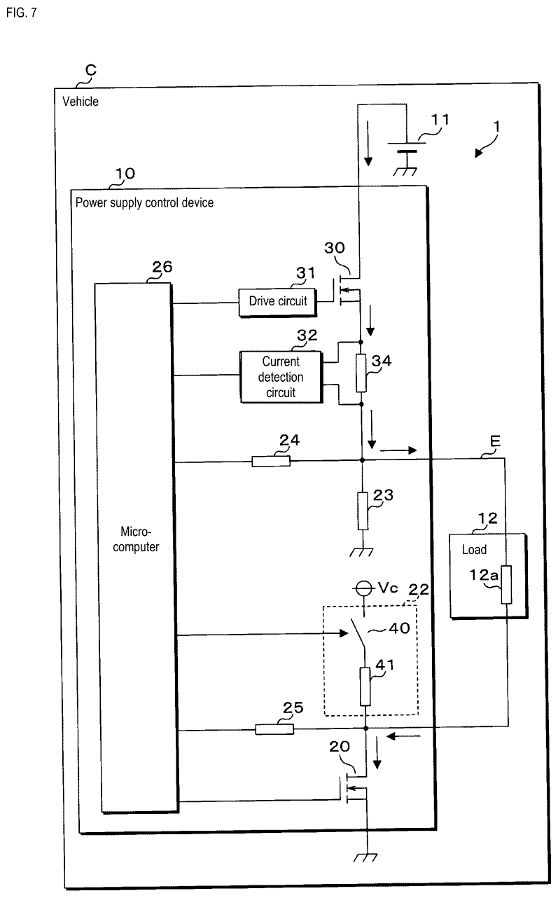

FIG. 7 is a block diagram illustrating a configuration of the main part of the power supply control device 10 according to Embodiment 2. The power supply control device 10 of Embodiment 2 includes the downstream switch 20, the series circuit 22, the first resistor 23, the upstream resistor 24, the downstream resistor 25, the upstream switch 30, the drive circuit 31, and the current detection circuit 32. The power supply control device 10 further includes a shunt resistor 34. The power supply control device 10 does not include the IPD 21.

The connection between the load resistor 12a, the downstream switch 20, the series circuit 22, the downstream resistor 25, and the drive circuit 31 is the same as in Embodiment 1. Similar to Embodiment 1, a constant voltage is applied to the series circuit 22. The connection between the drain and the gate of the upstream switch 30 is the same as in Embodiment 1.

The source of the upstream switch 30 is connected to one end of the shunt resistor 34. The other end of the shunt resistor 34 is connected to one end of the load resistor 12a. One end of the first resistor 23 and one end of the upstream resistor 24 are connected to a connection node between the shunt resistor 34 and the load resistor 12a. The connection node between the shunt resistor 34 and the load resistor 12a is a connection node between the upstream switch 30 and the load resistor 12a. The one end of the first resistor 23 is grounded. The other end of the upstream resistor 24 is connected to the A/D converter 53 of the microcomputer 26. The one end and the other end of the shunt resistor 34 are individually connected to the current detection circuit 32. The current detection circuit 32 is further connected to the A/D converter 52 of the microcomputer 26.

As in Embodiment 1, when the upstream switch 30 and the downstream switch 20 are on, a current flows from the positive terminal of the DC power source 11 to the negative terminal of the DC power source 11 through the current path E. On the current path E, a current flows to the upstream switch 30, the shunt resistor 34, the load resistor 12a, the downstream switch 20, and the negative terminal of the DC power source 11 in this order, as indicated by arrows. When the upstream switch 30 is on, a current flows from the positive terminal of the DC power source 11 to the upstream switch 30, the shunt resistor 34, and the load resistor 12a in this order.

The entire current output from the upstream switch 30 is input to the shunt resistor 34. Accordingly, the current value of the current flowing through the shunt resistor 34 matches the current value of a current flowing through the upstream switch 30. The resistance value of the shunt resistor 34 is a fixed value. Accordingly, the value of a voltage between the two ends of the shunt resistor 34 is proportional to the current value of the current flowing through the upstream switch 30. By detecting the value of the voltage between the two ends of the shunt resistor 34, the current detection circuit 32 detects the current value of the current flowing through the upstream switch 30. The current detection circuit 32 outputs the value of the voltage between the two ends of the shunt resistor 34 to the A/D converter 52 of the microcomputer 26 as analog current information.

By dividing the value of the voltage between the two ends of the shunt resistor 34 by the resistance value of the shunt resistor 34, the current value of the current flowing through the shunt resistor 34 is calculated. Therefore, the current information indicates a detected current value Id detected by the current detection circuit 32. Similar to Embodiment 1, the A/D converter 52 converts the analog current information into digital current information. The control unit 57 of the microcomputer 26 obtains the digital current information converted by the A/D converter 52. In Embodiment 2, the drive circuit 31 does not turn off the upstream switch 30 based on the detected current value Id or the temperature of the upstream switch 30.

### First Failure Voltage Value Vf1 and Second Failure Voltage Value Vf2

As mentioned in the description of Embodiment 1 above, the first failure voltage value Vf1 is equal to the first voltage value V1 when a half-on failure has occurred in the upstream switch 30 and the downstream switch 20 is on. Since the resistance value of the first resistor 23 is sufficiently larger than the resistance value of the load resistor 12a, the first failure voltage value Vf1 substantially matches the voltage value of a voltage obtained by a circuit including the upstream switch 30 and the shunt resistor 34, and the load resistor 12a dividing the power source voltage value Vb.

As mentioned in the description of Embodiment 1 above, the second failure voltage value Vf2 is equal to the second voltage value V2 when a half-on failure has occurred in the downstream switch 20 and the upstream switch 30 is on. Since the resistance value of the first resistor 23 is sufficiently larger than the resistance value of the load resistor 12a, the second failure voltage value Vf2 substantially matches the voltage value of a voltage obtained by a circuit including the shunt resistor 34 and the load resistor 12a, and the downstream switch 20 dividing the power source voltage value Vb.

### Failure Diagnosis

In Embodiment 1, when the upstream switch 30 is on, or a short circuit failure has occurred in the upstream switch 30, the first voltage value V1 is equal to the power source voltage value Vb. In Embodiment 2, when the upstream switch 30 is on or a short circuit failure has occurred in the upstream switch 30, and when the downstream switch 20 is off or an open circuit failure has occurred in the downstream switch 20, the first voltage value V1 is equal to the voltage value of a voltage obtained by the shunt resistor 34 and the first resistor 23 dividing the power source voltage value Vb. Since the first resistor 23 is sufficiently larger than the shunt resistor 34, that voltage value substantially matches the power source voltage value Vb.

As described above, the resistance value of the first resistor 23 is sufficiently larger than the resistance value of the load resistor 12a. Accordingly, when the upstream switch 30 is on or a short circuit failure has occurred in the upstream switch 30, and when the downstream switch 20 is on or a short circuit failure has occurred in the downstream switch 20, the first voltage value V1 is equal to the voltage value of a voltage obtained by division performed by the shunt resistor 34 and the load resistor 12a. Since the resistance value of the load resistor 12a is sufficiently larger than the resistance value of the shunt resistor 34, the voltage value substantially matches the power source voltage value Vb.

### Effects

The power supply control device 10 of Embodiment 2 achieves the same effects as those achieved by the power supply control device 10 of Embodiment 1 except for the effects achieved by failure detection performed by the drive circuit 31.

### Modifications

In Embodiments 1 and 2, it is sufficient that the upstream switch 30 and the downstream switch 20 are semiconductor switches. Therefore, the upstream switch 30 and the downstream switch 20 are not limited to N-channel FETs, and may be P-channel FETs, bipolar transistors, or the like.

Technical features (constituent components) described in Embodiments 1 and 2 can be combined with each other, and by combining them, new technical features can be formed.

The disclosed Embodiments 1 and 2 should be considered illustrative in all respects rather than restrictive. The scope of the disclosure is defined by the claims, not in the sense described above, and all modifications within the meaning and scope equivalent to the claims are intended to be included.

1. A power supply control device for controlling power supply to a load, comprising:
an upstream switch disposed upstream of the load in a current path for a current flowing through the load;
a downstream switch disposed downstream of the load in the current path;
a first resistor whose one end is connected to a connection node between the upstream switch and the load;
a series circuit whose one end is connected to a connection node between the load and the downstream switch, the series circuit including a second resistor and a connection switch that are connected in series to each other; and
a processing unit configured to execute processing,
wherein a constant voltage with respect to a potential of another end of the first resistor serving as a reference potential is applied to another end of the series circuit, and
the processing unit is configured to:
obtain a voltage value of a voltage at the connection node between the upstream switch and the load, or a voltage value of a voltage at the connection node between the load and the downstream switch, and
detect a failure of the upstream switch, the downstream switch, or the load based on the obtained voltage value.

2. The power supply control device according to claim 1,
wherein a current flows from one end of a DC power source to another end of the DC power source through the current path,
the processing unit is configured to:
give an instruction to turn on the upstream switch,
give an instruction to turn off the downstream switch, and
obtain a voltage value of a voltage at the connection node between the upstream switch and the load, or a voltage value of a voltage at the connection node between the load and the downstream switch, while the connection switch is off, and
detect an open circuit failure of the upstream switch when the obtained voltage value is less than a voltage threshold, and
the voltage threshold exceeds 0 V and is less than or equal to a value of a voltage between the one end and the other end of the DC power source.

3. The power supply control device according to claim 1,
wherein a current flows from one end of a DC power source to another end of the DC power source through the current path,
the processing unit is configured to:
give instructions to turn off the upstream switch and the downstream switch,
obtain a voltage value of a voltage at the connection node between the upstream switch and the load, or a voltage value of a voltage at the connection node between the load and the downstream switch, while the connection switch is off, and
detect a short circuit failure of the upstream switch when the obtained voltage value exceeds a second voltage threshold, and
the second voltage threshold is 0 V or more and is less than a value of a voltage between the one end and the other end of the DC power source.

4. The power supply control device according to claim 1,
wherein the processing unit is configured to:
give an instruction to turn off the upstream switch;
give an instruction to turn on the downstream switch;
obtain a voltage value of a voltage at the connection node between the upstream switch and the load, or a voltage value of a voltage at the connection node between the load and the downstream switch, while the connection switch is on; and
detect an open circuit failure of the downstream switch when the obtained voltage value exceeds a third voltage threshold, and
the third voltage threshold is 0 V or more, and is less than a voltage value obtained by the processing unit when the upstream switch, the downstream switch, and the connection switch are respectively off, off, and on.

5. The power supply control device according to claim 1,
wherein the processing unit is configured to:
give instructions to turn off the upstream switch and the downstream switch,
obtain a voltage value of a voltage at the connection node between the upstream switch and the load, or a voltage value of a voltage at the connection node between the load and the downstream switch, while the connection switch is on; and
detect a short circuit failure of the downstream switch when the obtained voltage value is less than a fourth voltage threshold, and
the fourth voltage threshold exceeds 0 V, and is less than or equal to a voltage value obtained by the processing unit when the upstream switch, the downstream switch, and the connection switch are respectively off, off, and on.

6. The power supply control device according to claim 1,
wherein the processing unit is configured to:
give instructions to turn off the upstream switch and the downstream switch;
obtain a voltage value of a voltage at the connection node between the load and the downstream switch while the connection switch is on; and
detect an open circuit failure of the load when the obtained voltage value exceeds a fifth voltage threshold, and
the fifth voltage threshold exceeds a voltage value obtained by the processing unit when the upstream switch, the downstream switch, and the connection switch are respectively off, off, and on, and is less than a voltage value of the constant voltage.

7. The power supply control device according to claim 1,
wherein a current flows from one end of a DC power source to another end of the DC power source through the current path,
the processing unit is configured to:
give instructions to turn on the upstream switch and the downstream switch;
obtain a voltage value of a voltage at the connection node between the upstream switch and the load while the connection switch is off; and
detect an open circuit failure of the upstream switch when the obtained voltage value is less than a sixth voltage threshold, and
the sixth voltage threshold exceeds 0 V and is less than or equal to a value of a voltage between the one end and the other end of the DC power source.

8. The power supply control device according to claim 1,
wherein a current flows from one end of a DC power source to another end of the DC power source through the current path,
the upstream switch is a semiconductor switch,
the processing unit is configured to:
give instructions to turn on the upstream switch and the downstream switch;
obtain a voltage value of a voltage at the connection node between the upstream switch and the load while the connection switch is off; and
detect a failure regarding a resistance value of the upstream switch when the obtained voltage value is less than a seventh voltage threshold, and
the seventh voltage threshold is less than or equal to a value of a voltage between the one end and the other end of the DC power source.

9. The power supply control device according to claim 1,
wherein a current flows from one end of a DC power source to another end of the DC power source through the current path,
the processing unit is configured to:
give instructions to turn on the upstream switch and the downstream switch;
obtain a voltage value of a voltage at the connection node between the load and the downstream switch while the connection switch is off; and
detect an open circuit failure of the downstream switch when the obtained voltage value exceeds an eighth voltage threshold, and
the eighth voltage threshold is 0 V or more, and is less than a value of a voltage between the one end and the other end of the DC power source.

10. The power supply control device according to claim 1,
wherein the processing unit is configured to:
give instructions to turn on the upstream switch and the downstream switch;
obtain a voltage value of a voltage at the connection node between the load and the downstream switch while the connection switch is off; and
detect a failure regarding a resistance value of the downstream switch when the obtained voltage value exceeds a ninth voltage threshold, and
the ninth voltage threshold is 0 V or more.

11. The power supply control device according to claim 1,
wherein the processing unit is configured to:
give instructions to turn on the upstream switch and the downstream switch;
obtain a current value of a current flowing through the upstream switch; and
detect an open circuit failure of the load when the obtained current value is less than a current threshold,
the current threshold exceeds a current value of a current flowing through the upstream switch when the upstream switch, the downstream switch, and the connection switch are respectively on, off, and off,
the current threshold is less than or equal to a current value of a current flowing through the upstream switch when the upstream switch and the downstream switch are on while the load is in a normal state, and
a resistance value of the load is less than a resistance value of the first resistor.

12. The power supply control device according to claim 1,
wherein the processing unit is configured to:
give instructions to turn on the upstream switch and the downstream switch;
obtain a current value of a current flowing through the upstream switch; and
detect a short circuit failure of the load when the obtained current value exceeds a second current threshold, and
the second current threshold is a current value of a current flowing through the upstream switch when the upstream switch and the downstream switch are on while the load is in a normal state.

13. The power supply control device according to claim 1,
wherein upon detection of a failure in the upstream switch, the downstream switch, or the load when instructions to turn on the upstream switch and the downstream switch have been given, the processing unit gives instructions to turn off the upstream switch and the downstream switch.

14. A failure detection method for detecting a failure of a circuit, the circuit including: an upstream switch disposed upstream of a load in a current path for a current flowing through the load; a downstream switch disposed downstream of the load in the current path; a first resistor whose one end is connected to a connection node between the upstream switch and the load; and a series circuit whose one end is connected to a connection node between the load and the downstream switch, the series circuit including a second resistor and a connection switch that are connected in series to each other, a constant voltage with respect to a potential of another end of the first resistor serving as a reference potential being applied to another end of the series circuit, the method comprising the steps, executed by a computer, of:
obtaining a voltage value of a voltage at the connection node between the upstream switch and the load, or a voltage value of a voltage at the connection node between the load and the downstream switch; and
detecting any failure of the upstream switch, the downstream switch, and the load based on the obtained voltage value.
